(19) United States
(12) Patent Application Publication
(10) Pub. No.: US 2012/0261763 A1
(43) Pub. Date: Oct. 18, 2012

(54) Semiconductor Structure and Method for Manufacturing the Same

(76) Inventors: Huaxiang Yin, Beijing (CN); Qiuxia Xu, Beijing (CN); Dapeng Chen, Beijing (CN)

(21) Appl. No.: 13/321,055

(22) PCT Filed: Apr. 19, 2011
(86) PCT No.: PCT/CN11/00685

§ 371 Date: Nov. 17, 2011

(30) Foreign Application Priority Data
Mar. 7, 2011 (CN) 201110053469.8

(51) Int. Cl. H01L 27/092; H01L 21/336

(52) U.S. Cl. 257/369; 438/591; 257/E27.062; 257/E21.409

(57) ABSTRACT

The present invention relates to a semiconductor and a method for manufacturing the same. The semiconductor structure comprises an NMOS device comprising a first gate structure and a PMOS device comprising a second gate structure; a first stress liner, at least formed on both sides of the first gate structure of said NMOS device; a second stress liner, at least formed on both sides of the second gate structure of said PMOS device; wherein said first stress liner is a spin-on glass (SOG) film with tensile stress, said second stress liner is formed of a material that can introduce compressive stress into the channel of the PMOS device. The present invention can reduce the difficulty of the process of manufacturing dual stress liner using the same material, e.g. nitride, and can reduce influence of nitride having a high dielectric constant upon the device interconnect delay while still maintaining the tensile strain advantage.

### FIELD OF THE INVENTION

The present invention relates to the semiconductor field, and more particularly relates to a semiconductor structure and method for manufacturing the same.

### BACKGROUND OF THE INVENTION

Theoretical and empirical researches have proved that when stress is applied into a channel of a transistor, the semiconductor lattice of a channel region is strained, the carrier mobility of the transistor is thus increased or decreased; however, it is also known that electron and hole have different responses to the same type of strain. For example, applying compressive stress in the longitudinal direction of current flow results in compressive strain of the lattice of the channel region which is advantageous for improving hole mobility, but correspondingly decreases electron mobility. Applying tensile stress in the longitudinal direction results in tensile strain of the lattice of the channel region which is advantageous for improving electron mobility, but correspondingly decreases hole mobility. As the feature size of a device constantly reduces, the strained channel engineering aiming at improving the channel carrier mobility performs an increasingly important function. According to this theory, many methods have been developed, wherein one method is to generate “local strain”, that is, using a local structure adjacent to the device channel or a process method to generate corresponding stress upon the channel region so as to generate strain. The local strain, for example, is via introduction of (dual) stress liner. At present, for a CMOS device, nitride (e.g., silicon nitride) dual stress liner is usually used for PMOS structure and NMOS structure thereof, that is, process conditions are controlled such that the same nitride material respectively generates compressive stress for PMOS structure and tensile stress for NMOS structure. However, for the same nitride material, it causes difficulty in process for both generating compressive stress on PMOS structure and tensile stress on NMOS structure; moreover, for the formation of dual nitride liner, it usually need to firstly form a nitride layer with a first type of stress (e.g. compressive stress) on the PMOS structure and the NMOS structure, then to mask one of the PMOS structure and the NMOS structure to protect it and thereafter to etch the nitride on the other structure, the above steps hence cause difficulty in selectively etching the same material; moreover, nitride having a high dielectric constant has adverse influence on device interconnect delay.

Considering the reasons stated above, there still exists a demand for a new method and semiconductor structure for realizing introduction of strain to CMOS device.

### SUMMARY OF THE INVENTION

In a first aspect, the present invention provides a semiconductor structure, comprising an NMOS device comprising a first gate structure and a PMOS device comprising a second gate structure; a first stress liner, at least formed on both sides of the first gate structure of said NMOS device; a second stress liner, at least formed on both sides of the second gate structure of said PMOS device; wherein said first stress liner is a spin-on glass (SOG) film with tensile stress, said second stress liner is formed of a material that can introduce compressive stress into the channel of the PMOS device.

In another aspect, the present invention provides a method for manufacturing a semiconductor structure, comprising: forming an NMOS device comprising a first gate structure and a PMOS device comprising a second gate structure, respectively; forming a first stress liner at least on both sides of the first gate structure of said NMOS device; forming a second stress liner at least on both sides of the second gate structure of said PMOS device; wherein said first stress liner is a spin-on glass (SOG) film with tensile stress, said SOG film is formed by forming SOG solution on the surface of said NMOS device and thereafter by thermal processing; and said second stress liner is formed of a material that can introduce compressive stress into the channel of the PMOS device.

In still another aspect, the present invention provides a use of the semiconductor structure in the first aspect of the present invention and the method for manufacturing the semiconductor structure in the second aspect of the present invention for manufacturing a corresponding CMOS device by the gate-first or gate-last process of the CMOS device.

The following advantages can be achieved by respectively forming a tensile stress liner of a first material and forming a compressive stress liner of a second material different from the first material (specifically, the first material is SOG film, the second material is nitride with compressive stress) on the NMOS and PMOS region: (1) effectively reducing the difficulty in the process of forming thin films with different stress types using the same nitride material (e.g. silicon nitride); (2) reducing the difficulty of selectively etching the thin films with different stress types simultaneously; (3) forming a high tensile stress film with low cost; (4) reducing the influence upon the device interconnect delay by the nitride having a high dielectric constant while still maintaining the tensile strain, because the normal nitride having a high dielectric constant is replaced by the SOG film having a low dielectric constant and with tensile stress.

### BRIEF DESCRIPTION OF THE DRAWINGS

In order to better understand the present invention and show how it takes effect, now reference is made to the Figures by giving examples, wherein:

FIG. 1 shows a primary structure used in the present invention;

FIG. 2 shows the structure after a first stress liner is formed on the surface of the PMOS device and the NMOS device shown in FIG. 1;

FIG. 3 shows the structure after a first patterned mask is formed;

FIG. 4 shows the structure after the exposed first stress liner on the top of the PMOS device is removed using the first mask;

FIG. 5 shows the structure after a second stress liner is formed on the whole structure;

FIG. 6 shows the structure after a second patterned mask is formed;

FIG. 7 shows the structure after the second stress liner is selectively removed from the first stress liner on the NMOS region;

FIGS. 8a, 8b respectively show two exemplary structures after interconnecting dielectric and contact are formed; and

FIG. 9 shows steps of forming said structures.

### DETAILED DESCRIPTION OF THE INVENTION

One or more aspects of the embodiment of the present invention are described as follows with reference to the Figures, wherein generally the same element is denoted by the same reference sign throughout Figures. In the following description, for illustration purpose, many specifics are discussed to provide thorough understanding of one or more aspects of the embodiment of the present invention. However, it is obvious for those skilled in the art that one or more aspects of the present invention can be implemented using a few of said specifics.

In addition, although particular features or aspects is disclosed only by one of certain implements, yet such features or aspects may be combined with other features or aspects of other implements which may be expected and advantageous for any given or particular application.

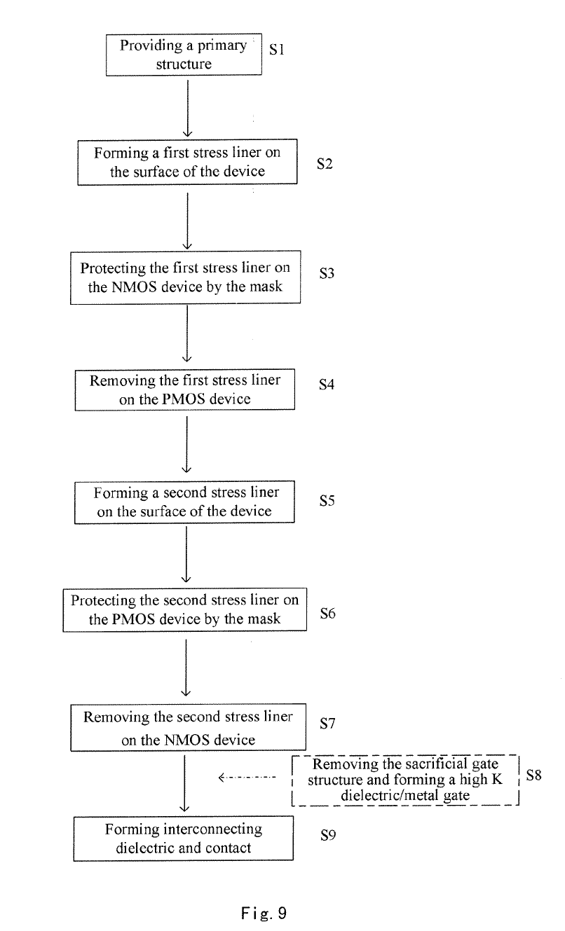

FIG. 1 shows a primary structure 10 used in the present invention, corresponding to step S1 in FIG. 9. The primary structure comprises a semiconductor substrate 100, an NMOS device 102A and a PMOS device 102B formed on the semiconductor substrate that are preferably separated from each other by an isolation region. The isolation region, for example, is a shallow trench isolation (STI) or a field isolation region, and the material of the isolation region may be with stress or without stress. The NMOS device comprises a channel, a first gate structure (comprising a gate dielectric layer 104A and a gate conductor 106A), a spacer 108A, source/drain and source/drain extension region 110A and a silicide contact (not shown). The PMOS device comprises a channel, a second gate structure (comprising a gate dielectric layer 104B and a gate conductor 106B), a spacer 108B, source/drain and source/drain extension region 110B and a silicide contact (not shown).

The semiconductor substrate in the primary structure may be any type known in the electronic field, for example, a bulk semiconductor, a semiconductor on insulator (SOD. And, the semiconductor substrate may be strained, may not be strained or contain therein a strained region or a non-strained region.

The material of said gate dielectric layers 104A and 104B may include a high K (dielectric constant) material or a low K material, e.g., SiO₂, ZrO₂, HfO₂, Al₂O₃, HfSiO, HfSiON and/or the combination thereof. For a traditional CMOS device, said gate dielectric layer normally is the low K material, e.g. SiO₂, while for gate-first process or gate-last process for a high K dielectric/metal gate, the dielectric layer may be the high K material, e.g. ZrO₂, HfO₂, Al₂O₃, HfSiO, HfSiON and/or the combination thereof. The material of the gate dielectric layers 104A and 104B may be the same or different, preferably the same. Said gate dielectric layers may be formed by thermal growth process, e.g., oxidation, nitridation, or oxynitridation. Alternatively, the gate dielectric layers may be formed by deposition process, e.g., chemical vapor deposition (CVD), plasma assisted CVD, atomic layer deposition (ALD), evaporation, reactive sputtering, chemical solution deposition or other similar deposition processes, said gate dielectric layers also may be formed by the combination of any ones of said processes.

After the gate dielectric layers 104A and 104B are formed, gate conductors 106A and 106B are respectively formed on the gate dielectric layers 104A and 104B, the gate conductors may comprise any type of conductive material, including but not limited to polysilicon, metal or metal alloy, silicide, conductive nitride, polycrystalline SiGe or the combination thereof. For a traditional CMOS device, said gate conductors normally may be polysilicon, for example, while for gate-first process for a high K dielectric/metal gate, the gate conductors may be metal or metal alloy. The material of the gate conductor 106A of the NMOS and the gate conductor 106B of the PMOS may be the same or different, preferably the same. In the manufacturing process, for the preparation process of a traditional CMOS device or for the gate-first process for a high K dielectric/metal gate, for example, the gate conductor layers 106A and 106B are respectively formed on the gate dielectric layers 104A and 104B using the deposition process, then the gate structures are respectively formed using the selective etching method. While for the gate-last process for a high K dielectric/metal gate, further steps are needed, which will be described later.

Source/drain and source/drain extension regions 110A, 110B are formed using ion implantation and annealing steps. The conditions for ion implantation and annealing are well known to those skilled in the art. In either case, in order not to blur the substance of the present invention, those skilled in the art may get to learn the specifics of these steps by referring to other published documents and patents.

After each MOS region is formed, a silicide contact is formed using a process well known in the art.

Alternatively, a tensile stress source 112A, e.g. SiC, or any type of tensile stress source which can be formed by any future technology, may be embedded on both sides of the channel of the NMOS device, i.e., in the source and drain regions; also, compressive stress source 112B, e.g., SiGe, or any type of compressive stress source which can be formed by any future technology, may be embedded on both sides of the channel of the PMOS device, i.e., in the source and drain regions; or, not only the tensile stress source 112A is formed in the NMOS, but also the compressive stress source 112B is formed in the PMOS.

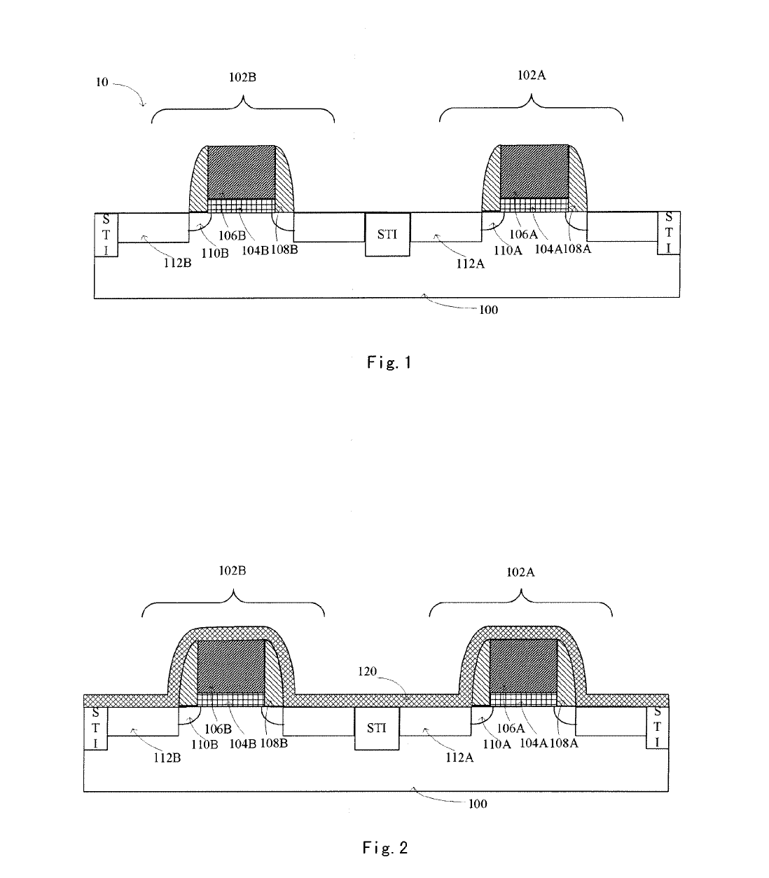

FIG. 2 shows the structure after a first stress liner 120 is formed on the surface of the PMOS device and the NMOS device as shown in FIG. 1, that is, on both sides and the top of each gate structure, corresponding to step S2 in FIG. 9. For the shown embodiment, the first stress liner is of tensile stress.

The first stress liner 120 is a spin-on glass (SOG) film. The material of said SOG film preferably is the combination of ethanol with at least one of the following: Siloxanes, Hi-organosiloxanes, Silicates, Doped-silicates material. The SOG film also may be composed of other oxides or low K oxide materials: e.g., phosphorus-doped SiO₂ (PSG), boro-phospho-doped SiO₂ (BPSG), fluorine-doped SiO₂ (SiOF), carbon and fluorine-doped SiO₂ (SiCOF), Hydrogen Silsesquioxane (HSQ), and Methylsilsesquioxane (MSQ).

Various methods in the semiconductor manufacturing process may be considered to be used to form the SOG film. For example, as a method, a wafer is rotated, and SOG solution is dripped from thereabove, the SOG solution is then spread and coated onto the surface of the PMOS and NMOS device via rotation centrifugal force. After the SOG solution is coated, the devices are thermally processed (dried and cured/sintered) such that the organic solvent of the SOG solution evaporates, to thereby form a silicon oxide film, i.e., a SOG film. The SOG film naturally has tensile stress in that it has apparent contracting characteristics. Moreover, the dielectric constant of the SOG film is lower than that of nitride, thus, the overall dielectric constant of the interconnecting dielectric mentioned later can be reduced and the parasitic capacitance formed between the device and the conductive material in the contact hole can be reduced, further, the interconnect conduction delay can be reduced.

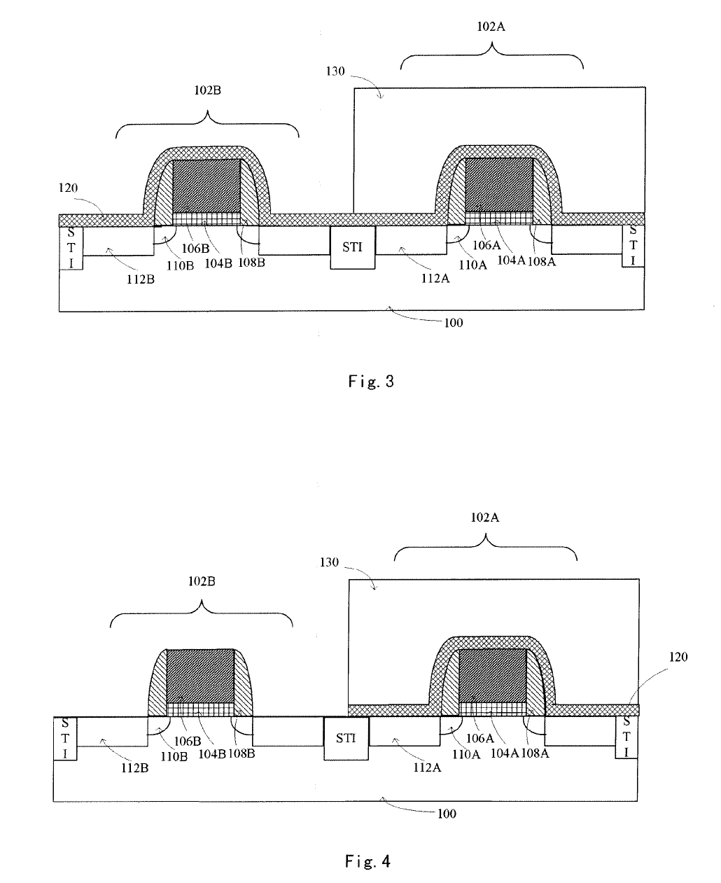

FIG. 3 shows the structure after a first patterned mask 130 is formed, corresponding to step S3 in FIG. 9. Said mask protects the NMOS device region shown in FIG. 2. The first patterned mask 130 may be a hard mask, such as SiO₂, or photoresist, which is formed by deposition (e.g. plasma-enhanced CVD (PECVD) and spin coating) and photolithography. As shown in FIG. 3, the PMOS region is not protected by the first patterned mask.

FIG. 4 shows the structure after the exposed first stress liner 120 is removed from the top of the PMOS device using the first mask, corresponding to step S4 in FIG. 9. Preferably, the exposed first stress liner 120 is removed by using anisotropic etching process. The first patterned mask 130 is then removed.

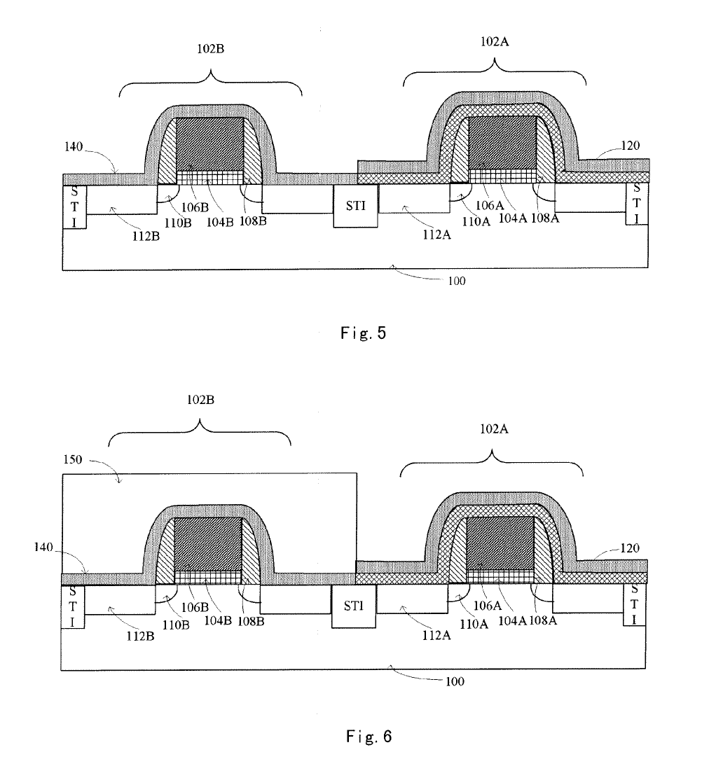

FIG. 5 shows the structure after a second stress liner 140 is formed on the whole structure, corresponding to step S5 in FIG. 9. The second stress liner is compressively strained. The second stress liner may be formed of any material that can introduce compressive stress into the channel of the device, including but not limited to silicon nitride, silicon oxynitride or other similar materials. Typically, it is formed of silicon nitride. The second stress liner 140 may be formed by using various chemical vapor deposition processes, including, e.g. low pressure CVD, PECVD, fast heating CVD. The stress type, for example, is controlled by deposition conditions. Such control is well known to those skilled in the art.

FIG. 6 shows the structure after a second patterned mask 150 is formed, corresponding to step S6 in FIG. 9. Said mask protects the PMOS device region shown in FIG. 5. The second patterned mask 150 may be a hard mask, such as SiO₂, or photoresist, which is formed by deposition (e.g. plasma-enhanced CVD (PECVD) and spin coating) and photolithography. As shown in FIG. 6, the NMOS region is not protected by the second patterned mask.

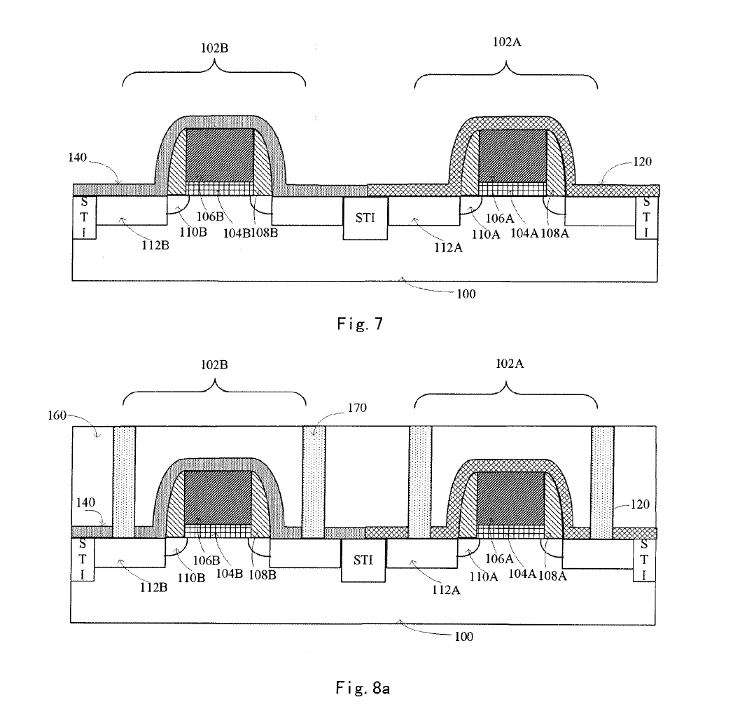

FIG. 7 shows the structure after the second stress liner 140 is selectively removed from the first stress liner 120 on the NMOS region, corresponding to step S7 in FIG. 9. Such selective removing is realized by firstly providing the second patterned mask 150 on the top of the region of the PMOS device and thereafter selectively etching the exposed second stress liner 140. The second patterned mask 150 is then removed. As such, the first stress liner is formed on the surface of the NMOS device, i.e., on both sides and on the top of the first gate structure; the second stress liner is formed on the surface of the PMOS device, i.e., on both sides and on the top of the second gate structure.

For steps corresponding to FIGS. 4-7, alternatively, the second stress liner 140 may be formed without a need to remove the first patterned mask 130, at the time, the second stress liner 140 partially covers the first patterned mask 130. Then, in the step corresponding to FIG. 7, the exposed second stress liner 140 and the first patterned mask 130 below it are removed sequentially.

Preferably, said SOG film also may be processed by one of the fast thermal annealing (preferably, 350° C.-1100° C., 1 ns-100 s), ultraviolet assisted thermal processing (UVTP), plasma processing, laser annealing (ELA) or the combination thereof. Through said processes, the SiH bond and NH bond in the SOG film are opened. The hydrogen atoms in the adjacent broken bonds combine to form hydrogen in molecular form, the hydrogen spreads from the film, and thus forms dangling bonds and micropores, the dangling bonds crosslink such that the micropores contract to obtain minimum surface energy, the device structure tends to resist the contraction, thus the tensile stress of said SOG film is further enhanced.

Meanwhile, the stress of the second stress liner also may be enhanced by one of the fast thermal annealing (preferably, 350° C.-1100° C., 1 ns-100 s), ultraviolet assisted thermal processing (UVTP), plasma processing, laser annealing (ELA) or the combination thereof.

Fast thermal annealing (preferably, 350° C.-1100° C., 1 ns-100 s) and laser annealing (ELA) also may serve as means for activating carriers of the source/drain doped regions.

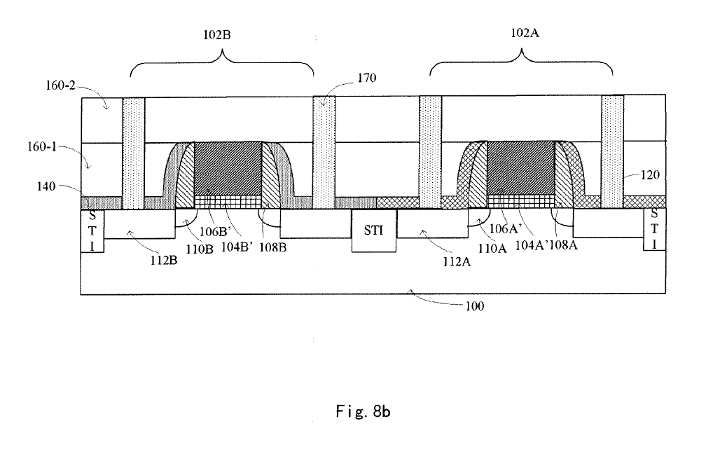

In one embodiment, for the preparation process of a traditional CMOS device or for the gate-first process for a high K dielectric/metal gate, then the CMOS device may be completed through continuous conventional processes, corresponding to step S9 in FIG. 9. Said structure is as shown in FIG. 8a, which is formed by forming interconnecting dielectric 160 with contact holes on the structure of FIG. 7 and then filing the contact holes with conductive material 170. The interconnecting dielectric comprises silicon oxide, organic silicate glass, siloxane, silsesquioxane or multi-layer structure thereof. The interconnecting dielectric is formed by traditional deposition process, for example, PECVD and spin coating. The contact holes are formed by photolithography and etching. The conductive material 170 may comprise conductive metal, metal alloy, metal silicide, metal nitride or doped-polysilicon. Sputtering, plating, evaporation, CVD, PECVD and other similar deposition processes may be used for forming the conductive material 170.

In another embodiment, for the gate-last process for a high K dielectric/metal gate, after the formation of said stress liner structure and annealing processing in FIGS. 4-7, the additional step S8 in FIG. 9 is needed: depositing first interconnecting dielectric 160-1 comprising silicon oxide, organic silicate glass, siloxane, silsesquioxane or multi-layer structure thereof; planarizing the interconnecting dielectric; removing the stress liner on the original gate structure (comprising the gate conductors 106A, 106B and the gate dielectric layers 104A, 104B); exposing the original gate structure (usually called sacrificial gate structure in the gate-last process for a high K dielectric/metal gate), wherein said gate conductors 106A, 106B in the high K dielectric/metal gate are, for example, polysilicon and other materials, thus, the first stress liner is only maintained on both sides of the first gate structure while it does not exist on the top thereof, and the second stress liner is only maintained on both sides of the second gate structure while it does not exist on the top thereof; and sequentially forming new high K gate dielectric layers 104A′, 104B′ (which may be ZrO₂, HfO₂, Al₂O₃, HfSiO, HfSiON and/or the combination thereof) and new metal gate conductors 106A′, 106B′ (which may be metal or metal alloy) after removing the gate conductors 106A, 106B and the gate dielectric layers 104A, 104B (e.g. through selective etching), thus forming a high K dielectric/metal gate structure, as shown in FIG. 8b. However, the embodiment of the present invention is not limited to this. Alternatively, in the condition that the gate dielectric layers 104A and 104B under the sacrificial gate conductors are already the high K material, the gate dielectric layers 104A and 104B may be maintained in intact or substantially in intact, in this case, it only needs to form new metal gate conductors 106A′ and 106B′ on the gate dielectric layers 104A and 104B within the opening gate region.

Thereafter, a structure shown in FIG. 8b, which comprises second interconnecting dielectric 160-2 with contact holes, is formed, wherein the contact holes are filled with the conductive material 170, corresponding to step S9 in FIG. 9.

In sum, comparing to the device and method that use the same material (e.g. nitride) as the dual stress liner in the prior art, the difficulty of the process of forming thin films with different stress types using the same nitride material (e.g. silicon nitride) can be effectively reduced through the structure and method for forming a compressive stress liner and a SOG film tensile stress liner on the PMOS and NMOS region, respectively; meanwhile the difficulty of selectively etching such thin films with different stress types can be reduced; a high tensile stress thin film can be formed with low cost; and because the normal nitride having a high dielectric constant is replaced by the SOG film having a low dielectric constant, the overall dielectric constant of the interconnecting dielectric and the parasitic capacitance formed between the device and the conductive material in the contact hole can be reduced, thus reducing the interconnect conduction delay, while the advantage of the tensile strain can be still maintained.

What have been stated above are only preferred embodiments of the present invention and do not make any limitation to the present invention. For example, although the embodiment describes the steps of firstly forming a tensile stress liner and then forming a compressive stress liner, yet for those skilled in the art, it is obvious that a compressive liner may be formed firstly and a tensile liner may be formed thereafter. At the time, the sequence of some processes is altered. Therefore, various modifications and variations can be made without departing from the principle of the technical method of the present invention and the protection scope of the appended claims.

What is claimed is:

1. A semiconductor structure, comprising:
an NMOS device (102A) comprising a first gate structure and a PMOS device (102B) comprising a second gate structure;
a first stress liner (120), at least formed on both sides of the first gate structure of said NMOS device;
a second stress liner (140), at least formed on both sides of the second gate structure of said PMOS device;
wherein said first stress liner is a spin-on glass (SOG) film with tensile stress, and said second stress liner is formed of a material that can introduce compressive stress into a channel of the PMOS device.

2. The semiconductor structure according to claim 1, wherein said first gate structure comprises a first dielectric layer (104A, 104A′) and a first gate conductor (106A, 106A′), said second gate structure comprises a second gate dielectric layer (104B, 104B′) and a second gate conductor (106B, 106B′); and wherein said first gate dielectric layer and second dielectric layer are low dielectric constant (K) or high K materials, said first gate conductor and second gate comprise at least one of polysilicon, metal or metal alloy, silicide, conductive nitride and polycrystalline SiGe or the combination thereof.

3. The semiconductor structure according to claim 2, wherein the material of said SOG film is the combination of ethanol with at least one of the following: Siloxanes, Hi-organosiloxanes, Silicates, Doped-silicates material; or the material of said SOG film is one of phosphorus-doped SiO₂ (PSG), boro-phospho-doped SiO₂ (BPSG), fluorine-doped SiO₂ (SiOF), carbon and fluorine-doped SiO₂ (SiCOF), Hydrogen Silsesquioxane (HSQ), and Methylsilsesquioxane (MSQ).

4. The semiconductor structure according to claim 3, wherein said SOG film is a SOG film through one of fast thermal annealing, ultraviolet assisted thermal processing (UVTP), plasma processing, and laser annealing (ELA) or the combination thereof, dangling bonds and micropores formed in said SOG film make the tensile stress of said SOG film to be further enhanced.

5. The semiconductor structure according to claim 1, wherein said second stress liner is formed of nitride.

6. A method for manufacturing a semiconductor structure, comprising:
forming an NMOS device (102A) comprising a first gate structure and a PMOS device (102B) comprising a second gate structure, respectively;
forming a first stress liner (120) at least on both sides of the first gate structure of said NMOS device;
forming a second stress liner (140) at least on both sides of the second gate structure of said PMOS device;
wherein said first stress liner is a spin-on (SOG) film with tensile stress, said SOG film is formed by forming SOG solution on the surface of said NMOS device and then by thermal processing; and the second stress liner is formed of a material that can introduce compressive stress into a channel of the PMOS device.

7. The method for manufacturing a semiconductor structure according to claim 6, wherein forming said first gate structure comprises forming a first dielectric layer (104A, 104A′) and a first gate conductor (106A, 106A′), forming said second gate structure comprises forming a second gate dielectric layer (104B, 104B′) and a second gate conductor (106B, 106B′), and wherein said first gate dielectric layer and second dielectric layer are low dielectric constant (K) or high K materials, said first gate conductor and second gate comprise at least one of polysilicon, metal or metal alloy, silicide, conductive nitride, and polycrystalline SiGe or the combination thereof.

8. The method for manufacturing a semiconductor structure according to claim 7, wherein the material of said SOG film is the combination of ethanol with at least one of the following: Siloxanes, Hi-organosiloxanes, Silicates, Doped-silicates material; or the material of said SOG film is one of phosphorus-doped SiO₂ (PSG), boro-phospho-doped SiO₂ (BPSG), fluorine-doped SiO₂ (SiOF), carbon and fluorine-doped SiO₂ (SiCOF), Hydrogen Silsesquioxane (HSQ), and Methylsilsesquioxane (MSQ).

9. The method for manufacturing a semiconductor structure according to claim 8, wherein said SOG film is a SOG film through one of fast thermal annealing, ultraviolet assisted thermal processing (UVTP), plasma processing, and laser annealing (ELA) or the combination thereof, forming dangling bonds and micropores in said SOG film such that the tensile stress of said SOG film is further enhanced.

10. The method for manufacturing a semiconductor structure according to claim 9, wherein said fast thermal annealing is implemented under the process conditions of 350° C.-1100° C., 1 ns-100 s.

11. The method for manufacturing a semiconductor structure according to claim 6, wherein said compressive stress liner is formed of nitride.

12. A use of Said semiconductor structure according to claim 1 for manufacturing a corresponding CMOS device by the gate-first or gate-last process of the CMOS device.

13. A use of said method for manufacturing a semiconductor structure according to claim 6 for manufacturing a corresponding CMOS device by the gate-first or gate-last process of the CMOS device.
